(19) United States
(12) Patent Application Publication
(10) Pub. No.: US 2026/0068767 A1
(43) Pub. Date: Mar. 5, 2026

(54) FLEXIBLE PROCESSING UNIT PLACEMENT ON STACKED THREE-DIMENSIONAL DYNAMIC RANDOM-ACCESS MEMORY (3D DRAM) FOR NEAR-MEMORY COMPUTING

(71) Applicant: QUALCOMM Incorporated, San Diego, CA (US)

(72) Inventors: Mustafa BADAROGLU, San Diego, CA (US); Woo Tag KANG, San Diego, CA (US); Jihong CHOI, San Diego, CA (US); Zhongze WANG, San Diego, CA (US); Giridhar NALLAPATI, San Diego, CA (US); Periannan CHIDAMBARAM, San Diego, CA (US)

(21) Appl. No.: 19/311,932

(22) Filed: Aug. 27, 2025

Related U.S. Application Data
(60) Provisional application No. 63/689,375, filed on Aug. 30, 2024.

(51) Int. Cl. H01L 25/065; H01L 25/18

(52) U.S. Cl. CPC H01L 25/0657

(57) ABSTRACT

A three-dimensional (3D) stacked memory package is described. The 3D stacked memory package includes a plurality of memory dies stacked on the base die. The 3D stacked memory package also includes a package substrate supporting the base die. The 3D stacked memory package further includes a plurality of processing units (PUs) arranged on the base die. The plurality of processing units are located at different locations of the base die. The 3D stacked memory package also includes one or more system buses on the base die and coupled between the one or more PUs and through silicon via (TSV) groups of the plurality of memory dies landing on the base die.

### CROSS-REFERENCE TO RELATED APPLICATION

The present Application for Patent claims the benefit of U.S. Provisional Ser. No. 63/689,375 entitled “FLEXIBLE PROCESSING UNIT PLACEMENT ON STACKED THREE-DIMENSIONAL DYNAMIC RANDOM-ACCESS MEMORY (3D DRAM) FOR NEAR-MEMORY COMPUTING,” filed Aug. 30, 2024, assigned to the assignee hereof, and expressly incorporated herein by reference in its entirety.

### BACKGROUND OF THE DISCLOSURE

### 1. Field of the Disclosure

Aspects of the present disclosure relate to semiconductor memory devices and, more particularly, to a flexible processing unit placement on stacked three-dimensional dynamic random-access memory (3D DRAM) for near-memory computing.

### 2. Description of the Related Art

Memory is a vital component for wireless communications devices. For example, a cell phone may integrate memory as part of an application processor, such as a system-on-chip (SoC) including a central processing unit (CPU), a graphics processing unit (GPU), and a neural processing unit (NPU). Successful operation of some wireless applications depends on the availability of a high-capacity and low-latency memory solution for scalability of processor workloads. A semiconductor memory device solution for providing a high-capacity, low-latency, and high-bandwidth memory is a goal for system designers.

Semiconductor memory devices include, for example, static random-access memory (SRAM) and dynamic random-access memory (DRAM). In practice, memory intensive applications (e.g., artificial intelligence (AI)) consume extensive amounts of DRAM data. State of the art high-bandwidth memory (HBM) DRAM provides advantages in performance and power for memory-demanding workloads such as generative-AI. In practice, an HBM DRAM stack is supported by a base die.

Unfortunately, significant restrictions on the base die complicate the formation of a custom compute die for enhancing the capabilities of the HBM DRAM stack. Fine-grain microbank placement and wide-input/output (IO) through silicon vias (TSVs) from the DRAM banks cause significant obstructions for the utilization of the base die on the 3D stacked DRAM die. This limits the DRAM bandwidth and forces centralization of a TSV bus in a 3D stacked DRAM (e.g., HBM). Placing TSVs at the center of HBM causes long signal routings, penalizing latency, and energy of data movement. A flexible processing unit placement on stacked 3D DRAM for near-memory computing, is desired.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

A three-dimensional (3D) stacked memory package is described. The 3D stacked memory package includes a plurality of memory dies stacked on the base die. The 3D stacked memory package also includes a package substrate supporting the base die. The 3D stacked memory package further includes a plurality of processing units (PUs) arranged on the base die. The plurality of processing units are located at different locations of the base die. The 3D stacked memory package also includes one or more system buses on the base die and coupled between the one or more PUs and through silicon via (TSV) groups of the plurality of memory dies landing on the base die.

A method of forming a three-dimensional (3D) stacked memory package is described. The method includes stacking a plurality of memory dies on a base die supported by a package substrate. The method also includes forming an array of processing units (PUs) on the base die. The PUs may be located at different locations of the base die. The method further includes forming one or more system buses on the base die and coupled between the array of PUs and a group of through silicon vias (TSVs) of the plurality of memory dies landing on the base die.

This has outlined, broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for conducting the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure. Other objects and advantages associated with the aspects disclosed herein will be apparent to those skilled in the art based on the accompanying drawings and detailed description.

### BRIEF DESCRIPTION OF THE DRAWINGS

For a more complete understanding of the present disclosure, reference is now made to the following description taken in conjunction with the accompanying drawings.

FIG. 1 illustrates an example implementation of a system-on-chip (SoC), which includes a high-bandwidth three-dimensional (3D) stacked memory having a base die configured for flexible processing unit (PU) placement, in accordance with various aspects of the present disclosure.

FIGS. 2A and 2B illustrate perspective and layout views, respectively, of a high-bandwidth three-dimensional (3D) stacked memory chip having a base die configured with compute logic and without memory power grid restrictions, according to various aspects of the present disclosure.

FIG. 3 illustrates an extreme-bandwidth three-dimensional (3D) stacked memory chip, having a base die configured for flexible processing unit (PU) placement, according to various aspects of the present disclosure.

FIG. 4 is an overhead view of the extreme-bandwidth 3D stacked memory chip of FIG. 3, having the base die configured for flexible processing unit (PU) placement, according to various aspects of the present disclosure.

FIG. 5 is a cross-sectional view of the extreme-bandwidth 3D stacked memory chip of FIG. 3, having the base die configured for flexible processing unit (PU) placement, according to various aspects of the present disclosure.

FIGS. 6A to 6F illustrate a process of forming the extreme-bandwidth three-dimensional (3D) stacked memory chip of FIG. 3, having a base die configured for flexible processing unit (PU) placement, according to various aspects of the present disclosure.

FIG. 7 is a process flow diagram illustrating a method for forming an extreme-bandwidth three-dimensional (3D) stacked memory chip, having a base die configured for flexible processing unit (PU) placement, according to various aspects of the present disclosure.

FIG. 8 is a process flow diagram illustrating a method of an example implementation of the method illustrated in FIG. 7, according to various aspects of the present disclosure.

FIG. 9 is a block diagram showing an exemplary wireless communications system in which a configuration of the disclosure may be advantageously employed.

FIG. 10 is a block diagram illustrating a design workstation used for circuit, layout, and logic design of a semiconductor component, such as the disclosed high-bandwidth three-dimensional (3D) stacked memory chip.

Other objects and advantages associated with the aspects disclosed herein will be apparent to those skilled in the art based on the accompanying drawings and detailed description. In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Disclosed are three-dimensional (3D) stacked memory package and methods for fabricating the same. In an aspect, the 3D stacked memory package includes a plurality of memory dies stacked on the base die. The 3D stacked memory package also includes a package substrate supporting the base die. The 3D stacked memory package further includes a plurality of processing units (PUs) arranged on the base die. The plurality of processing units are located at different locations of the base die. The 3D stacked memory package also includes one or more system buses on the base die and coupled between the one or more PUs and through silicon via (TSV) groups of the plurality of memory dies landing on the base die. In this way, obstructions for placements of the processing units may be decreased significantly or even removed altogether. The resulting stacked memory package can allow for extreme high bandwidth memories.

The detailed description set forth below, in connection with the appended drawings, is intended as a description of various configurations and is not intended to represent the only configurations in which the concepts described may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form to avoid obscuring such concepts.

As described, the use of the term “and/or” is intended to represent an “inclusive OR,” and the use of the term “or” is intended to represent an “exclusive OR.” As described, the term “exemplary” used throughout this description means “serving as an example, instance, or illustration,” and should not necessarily be construed as preferred or advantageous over other exemplary configurations. As described, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches, repeaters, and/or buffers. As described, the term “proximate” used throughout this description means “adjacent, very near, next to, or close to.” As described, the term “on” used throughout this description means “directly on” in some configurations, and “indirectly on” in other configurations. It will be understood that the term “layer” includes film and is not construed as indicating a vertical or horizontal thickness unless otherwise stated. As described, the term “substrate” may refer to a substrate of a diced wafer or may refer to a substrate of a wafer that is not diced. Similarly, the terms “chip”and “die”may be used interchangeably.

Memory is a vital component for processing systems, such as wireless communications devices. For example, a cell phone may integrate memory as part of an application processor, such as a system-on-chip (SoC) including a central processing unit (CPU), a graphics processing unit (GPU), and a neural processing unit (NPU). Successful operation of some wireless applications depends on the availability of a high-capacity and low-latency memory solution for scalability of processor workloads. A semiconductor memory device solution for providing a high-capacity, low-latency, and high-bandwidth memory is an existing goal for system designers.

Semiconductor memory devices include, for example, static random-access memory (SRAM) and dynamic random-access memory (DRAM). In practice, memory intensive applications (e.g., artificial intelligence (AI)) consume extensive amounts of DRAM. State of the art high-bandwidth memory (HBM) DRAM provides advantages in performance and power for memory-demanding workloads such as generative-AI. In practice, an HBM DRAM stack is supported by a base die. Unfortunately, significant restrictions on the base die complicate the formation of a custom compute die for enhancing the capabilities of the HBM DRAM stack.

For example, fine-grain micro-banks placement and wide-input/output (IO) through silicon vias (TSVs) from the micro-banks of the DRAM die cause significant obstructions for the utilization of the base die supporting the three-dimensional (3D) stacked DRAM die. This limits the DRAM bandwidth and forces centralization of a TSV bus in a 3D stacked DRAM (e.g., HBM). Placing TSVs at the center of HBM causes long signaling routes, penalizing latency, and energy of data movement. A flexible processing unit (PU) placement on a stacked 3D DRAM for near-memory computing, is desired.

Various aspects of the present disclosure are directed to a novel processing unit (PU) architecture that eliminates TSVs on a base die of 3D stacked DRAM die, which enables flexible placement of processing units (PUs). This PU architecture eliminates obstructions to PU placement, allowing any physical design placement. Additionally, this PU architecture supports extreme high-bandwidth (BW) DRAM (e.g., 10-100 times more than HBM) memories through wide-IO coming from the microbanks of the DRAM memory dies without any restriction on PU placement.

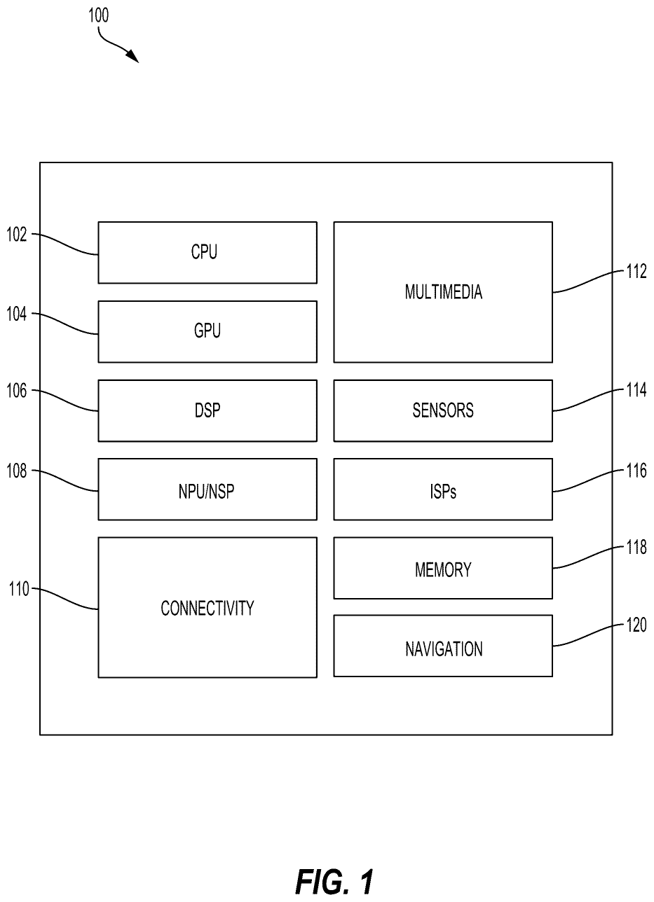

FIG. 1 illustrates an example implementation of a host system-on-chip (SoC) 100, which includes a high-bandwidth three-dimensional (3D) stacked memory having a base die configured for flexible processing unit (PU) placement, in accordance with aspects of the present disclosure. The host SoC 100 includes processing blocks tailored to specific functions, such as a connectivity block 110. The connectivity block 110 may include sixth generation (6G), connectivity fifth generation (5G) new radio (NR) connectivity, fourth generation long term evolution (4G LTE) connectivity, Wi-Fi connectivity, USB connectivity, Bluetooth® connectivity, Secure Digital (SD) connectivity, and the like.

In this configuration, the host SoC 100 includes various processing units that support multi-threaded operation. For the configuration shown in FIG. 1, the host SoC 100 includes a multi-core central processing unit (CPU) 102, a graphics processor unit (GPU) 104, a digital signal processor (DSP) 106, and a neural processor unit (NPU)/neural signal processor (NSP) 108. The host SoC 100 may also include a sensor processor 114, image signal processors (ISPs) 116, a navigation module 120, which may include a global positioning system, and a memory 118. The multi-core CPU 102, the GPU 104, the DSP 106, the NPU/NSP 108, and the multimedia engine 112 support various functions such as video, audio, graphics, gaming, artificial networks, and the like. Each processor core of the multi-core CPU 102 may be a reduced instruction set computing (RISC) machine, RISC-V, an advanced RISC machine (ARM), a microprocessor, or any reduced instruction set computing (RISC) architecture. The NPU/NSP 108 may be based on an ARM instruction set.

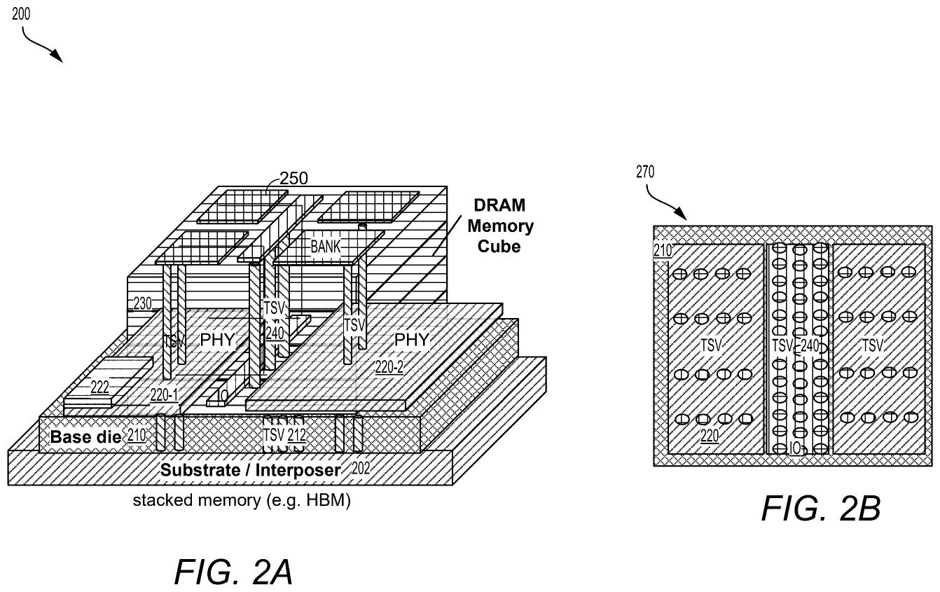

State of the art high-bandwidth memory (HBM) dynamic random-access memory (DRAM) provides advantages in performance and power for memory-demanding workloads such as generative-AI. In practice, an HBM DRAM stack is supported by a base die. Unfortunately, significant restrictions on the base die complicate the formation of a custom compute die for enhancing the capabilities of the HBM DRAM stack. Feedthrough power rail (e.g., Vdd-Vss) connections through the base die to a stacked DRAM supported by the base die create blockages in the layout of the base die and involve a change in the logic compute die every time a DRAM technology/vendor changes. Additionally, hot thermal logic below a 3D stacked DRAM limits the performance of the compute die due to thermal limits of DRAM operation. A high-bandwidth 3D stacked memory with a base die enabling compute logic without memory power grid restrictions is illustrated, for example, in FIGS. 2A and 2B.

FIGS. 2A and 2B illustrate perspective and layout views, respectively, of a high-bandwidth three-dimensional (3D) stacked memory chip having a base die configured with compute logic and without memory power grid restrictions, according to various aspects of the present disclosure. As shown in FIG. 2A, an extreme-bandwidth 3D stacked memory chip 200 includes a base die 210 (e.g., a first die) that is supported by a package substrate/interposer 202. In various aspects of the present disclosure, the base die 210 supports stacking of memory dies 230 (e.g., dynamic random-access memory (DRAM) dies) on the base die 210. In this example, the memory dies 230 are arranged using a back-to-face stacking of the DRAM dies on the face of the base die 210, according to a face-to-face (F2F) stacking. In some implementations, the base die 210 supports a stack of memory dies 230 (e.g., a stack of twelve (12) DRAM dies). The number of memory dies stacked on the base die 210 varies in different implementations.

In various aspects of the present disclosure, the memory dies 230 include memory banks (BANK) and an input/output (IO) block that utilize signal through silicon vias (e.g., signal TSVs 240) extending through the memory dies 230 (e.g., second die) and landing on the base die 210. As shown in FIG. 2A, the signal TSVs 240 provide signal transmission between the memory dies 230 and a physical layer (PHY) 220 of the base die 210. Additionally, the base die 210 includes a logic/signal TSV 212 to provide communication between the PHY 220 as well as a processing unit (PU) 222 and the package substrate/interposer 202. A PU as used herein refers to a group of processing logic circuits configured to perform logic functions, such as, for example, CPU, GPU, NPU, etc.

FIG. 2B illustrates a layout view 270 of the base die 210, further illustrating the signal TSVs 240 (e.g., DRAM power TSV, DRAM signal TSV, and logic power TSV) connections, according to various aspects of the present disclosure. Conventional feedthrough TSV connections present a considerable number of obstacles to flexibly design blocks on the base die 210 because the feedthrough TSV connections spread across an area defined by a shadow of the stack of memory dies 230. In practice, feedthrough TSVs increase the cost of the base die 210 due to the area consumed by both signal TSVs and power TSVs (e.g., ˜1K-2 K signal TSVs versus ˜10 K-20 K power TSVs) in the base die 210. Additionally, significant thermal block restrictions on the base die 210 complicate placement of hot compute cores (e.g., the PU 222) on the base die 210.

As shown in FIGS. 2A and 2B, TSV blocking on the base die 210 forces placement of the IO bus at the center of the DRAM die to reduce the TSV obstructions on the base die 210. In this instance, if the left-right is deemed to represent the X direction and up-down is deemed to represent the Y direction, then it may be said that the IO bus is forced to be placed substantially in a center of the X lateral width of the base die 310. Additionally, the extreme-bandwidth 3D stacked memory chip 200 includes a central bus 250 propagating signals to the center of the DRAM and back from the center to the PHY 220 located at the edge of base die 210. Unfortunately, the long data routing consumed by the central bus 250 on both the memory dies 230 and the base die 210 (e.g., 70-80% of energy/bit) impedes successful operation of the extreme-bandwidth 3D stacked memory chip 200.

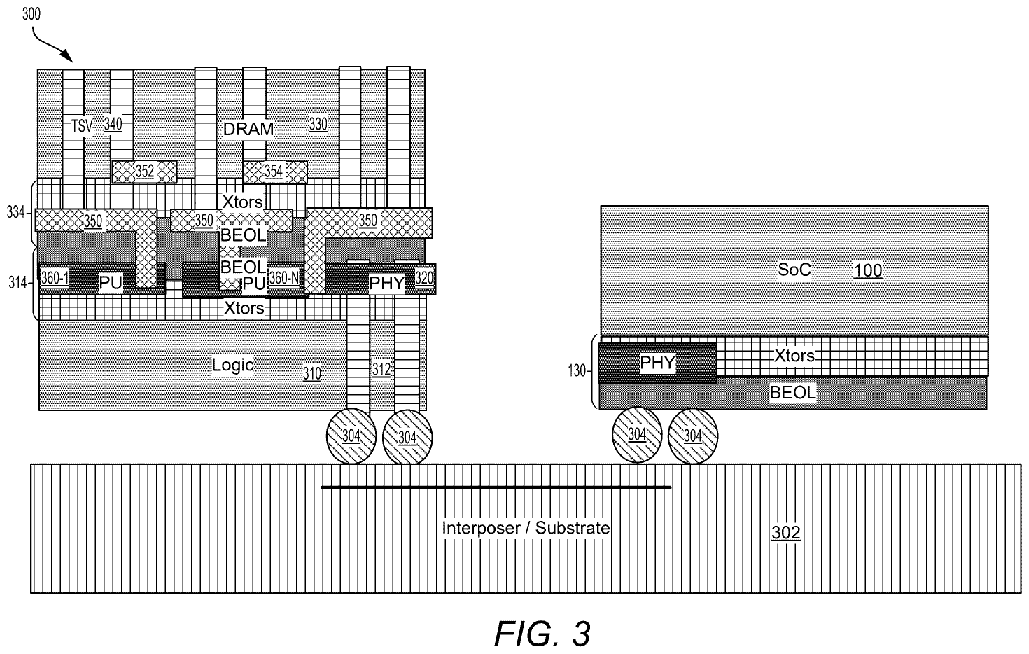

FIG. 3 illustrates an extreme-bandwidth three-dimensional (3D) stacked memory chip 300, having a base die configured for flexible processing unit (PU) placement, according to various aspects of the present disclosure. As shown in FIG. 3, the extreme-bandwidth 3D stacked memory chip 300 includes a base die 310 that is supported by a package substrate 302. Additionally, the package substrate 302 supports the SoC 100, including an active layer 130. In various aspects of the present disclosure, the base die 310 supports stacking of memory dies 330 (e.g., dynamic random-access memory (DRAM) dies) on the base die 310. The number of memory dies stacked on the base die 310 varies in different implementations.

In this example, the memory dies 330 are stacked on the base die according to face-to-face (F2F) stacking. That is, the base die 310 is arranged such that the face—the active portion of the base die 310—is oriented towards the memory dies 330, and the back is oriented towards the package substrate 302. Also, note that the face of the memory die 330 immediately above the base die 310 is oriented towards the face of the base die 310. Hence, the base die 310 and the memory die 330 are stacked face-to-face.

However, this is merely an example. While not shown, it is contemplated that the base die 310 and the first memory die 330 may be back-to-face (B2F) stacked. That is, the face of the base die 230 may still be oriented upwards—towards the memory dies 330. However, instead of the face, the back of the memory die 330 may be oriented towards base die 310 (not shown).

Also, recall that there can be multiple memory dies 330 above the base die 310. The orientations of these memory dies 330 are not limited. That is, a face of at least one memory die 330—i.e., a first memory die 330—may be oriented towards the base die 310. That is, the face of the first memory die 330 may be closer to the base die 310 than the back of the same first memory die 330. Alternatively or in addition thereto, a face of a second memory die 330 may be further away from the base die 310 than the back of the same second memory die 330.

Further, it is allowable that the multiple memory dies 330 have the same orientations—e.g., faces oriented to the base die 310 or backs oriented to the base die 310. However, while not shown in the figures, it is also contemplated there can be a mixture of orientations. That is, a first pair of vertically adjacent memory dies 330 may be stacked face-to-face. Alternatively or in addition thereto, a second pair of pair of vertically adjacent memory dies 330 may be stacked back-to-back. If both first and second pairs exist, then at least one memory die 330 of the first pair may be different from at least one memory die 330 of the second pair.

In this example, the base die 310 includes an active layer 314 having a front-end-of-line (FEOL) layer, including transistors (Xtors), and a back-end-of-line (BEOL) layer on the FEOL layer. Similarly, the DRAM die 330 includes an active layer 334 having an FEOL layer (e.g., Xtors), and a BEOL layer contacted to the BEOL layer of the base die 310, according to a face-to-face (F2F) stacking. According to various aspects to the present disclosure, the extreme-bandwidth 3D stacked memory chip 300 supports through silicon via (TSV) groups 340 to land on the base die 310 from micro-banks of the DRAM die 330 without any TSV obstructions and without enabling any flexible bus formation. In this example, the TSV groups 340 are distributed and non-gridded through the DRAM die 330.

According to various aspects of the present disclosure, the BEOL layer of the DRAM die 330 and the BEOL layer of the base die 310 are utilized to form one or more system buses 350. In this example, the system buses 350 provide lateral connections between the TSV groups 340 and an array of processing units (PUs) 360 in the active layer 314 of the base die 310. Additionally, micro-bank connections 352, 354 to the TSV groups 340 are also shown. In some implementations, the TSV groups 340 are rerouted using the system buses 350 to provide access to the array of PUs 360 and/or a physical IO module (PHY) 320 of the base die 310. Note that there can be multiple system buses 350. Also, some of the system buses 350 are NOT centrally located. That is, they are not limited to the central portion (e.g., NOT limited to the center of a lateral width) of the base die 310. This enables the placements of the PUs 360 in different locations of the base die 310. Package bumps 304 provide a connection with the interposer and/or package substrate 302 for the base die 310 and the SoC 100. In this example, locations of the system bus 350 are not aligned with the columns of the TSV groups 340, thus allowing more flexibility in routing.

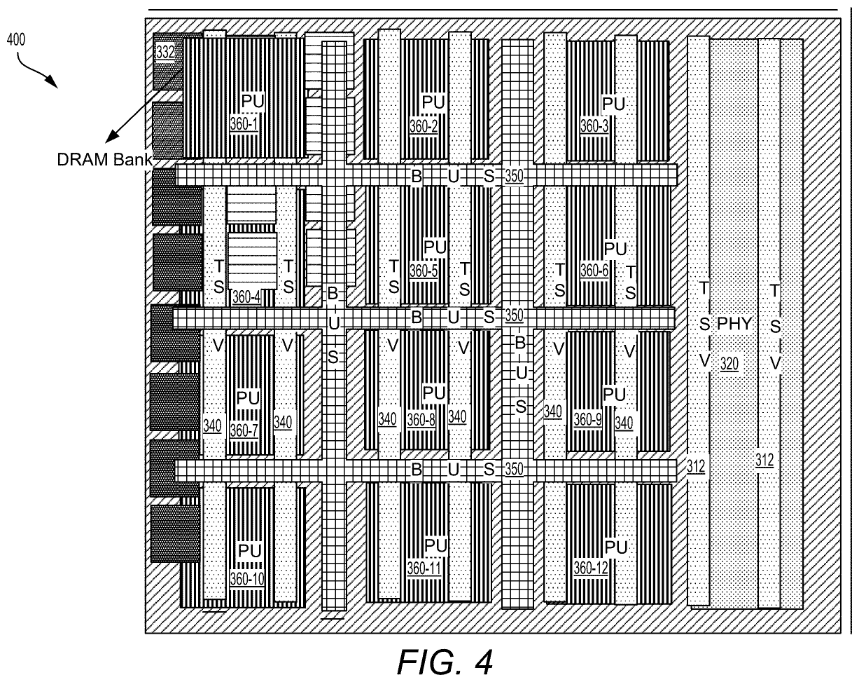

FIG. 4 is an overhead view 400 of the extreme-bandwidth 3D stacked memory chip 300 of FIG. 3, having the base die configured for flexible processing unit (PU) placement, according to various aspects of the present disclosure. FIG. 4 illustrates placement of an array of PUs 360 (360-1, 362-2, ..., 362-12) on the base die 310. The overhead view 400 of the extreme-bandwidth 3D stacked memory chip 300 of FIG. 3 further illustrates interconnects of the TSV groups 340 and lateral routing of the system bus 350 and DRAM banks 332. Again, the PUs 360 may be located at different locations of the base die 310, allowed by the flexibility of routing provided by the system buses 350.

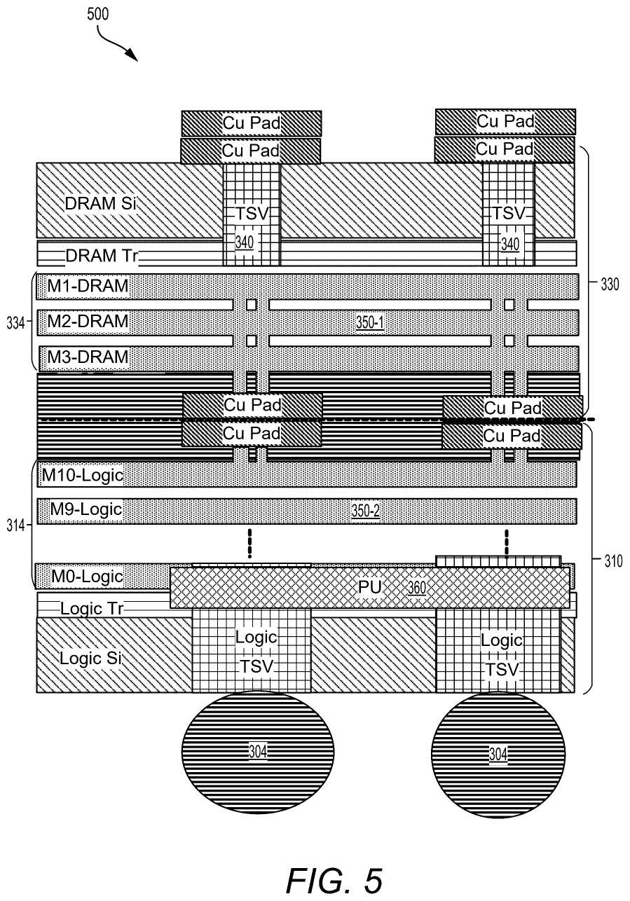

FIG. 5 is a cross-sectional view 500 of the extreme-bandwidth 3D stacked memory chip 300 of FIG. 3, having the base die configured for flexible processing unit (PU) placement, according to various aspects of the present disclosure. FIG. 5 illustrates placement of an array of the PUs 360 (360-1, 362-2, . . . , 362-12) on the base die 310. The cross-sectional view 500 of the extreme-bandwidth 3D stacked memory chip 300 of FIG. 3 further illustrates interconnects of the TSV groups 340 and lateral routing of the system bus 350 and DRAM banks 332 using the micro-bank connections 352, 354 to the TSV groups 340.

In this example, a first portion 350-1 of the system buses 350 is formed from a first metal layer (M1), a second metal layer (M2), and a third metal layer (M3) of the back-end-of-line (BEOL) of the active layer 324 of the DRAM die 330. Additionally, a second portion 350-2 of the system buses 350 is formed from a tenth metal layer (M10), and a ninth metal layer (M9) of the BEOL of the active layer 314 of the base die 310. The first portion 350-1 and the second portion 350-2 are contacted through pads (e.g., copper pads) to complete formation of the system buses 350. In this example, the system buses 350 are coupled to the PUs 360 of the base die 310, which is also coupled to logic through silicon via (TSV) and the package bumps 304. The lateral routing allows for system buses 350 to be formed so that the TSV obstructions.

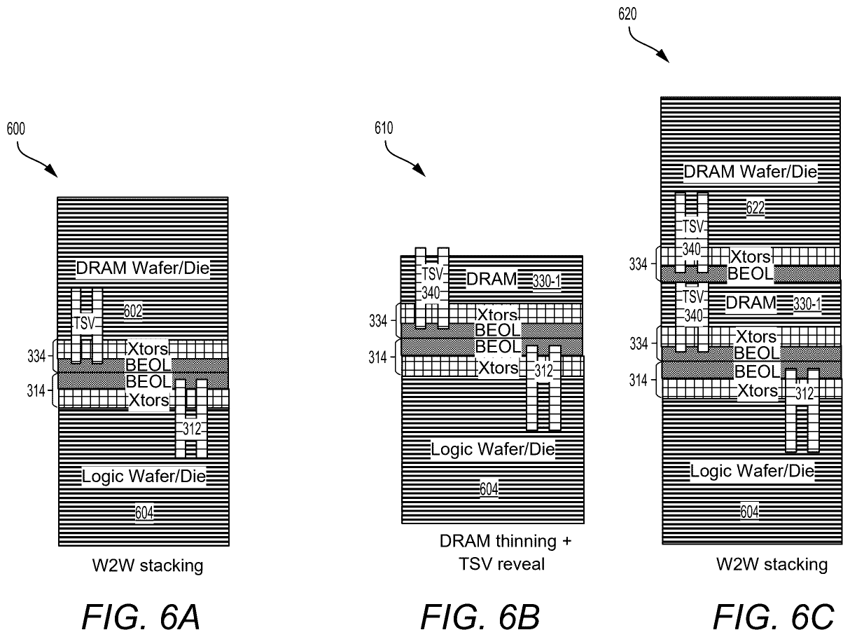

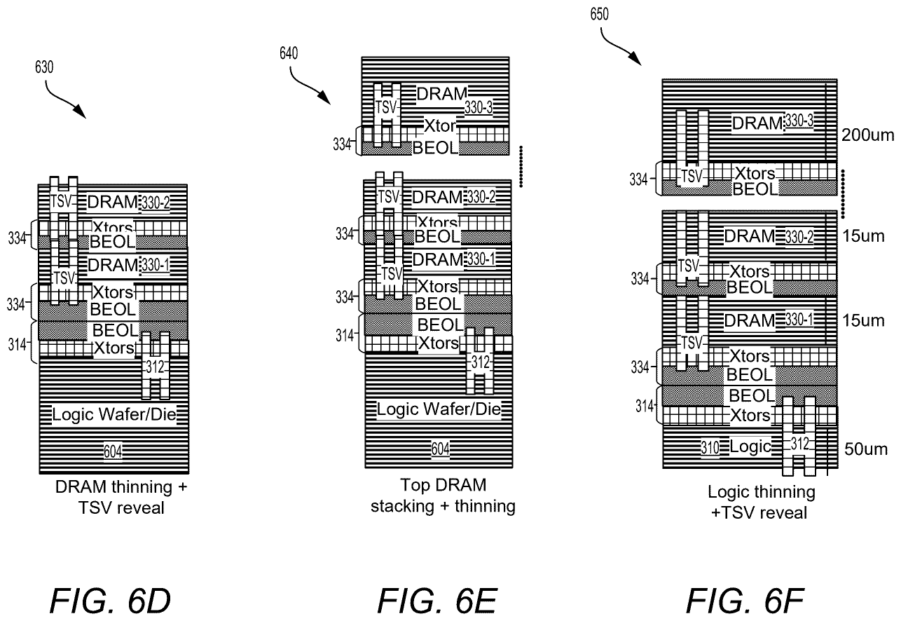

According to various aspects of the present disclosure, lateral routing of the system bus 350 avoids TSV blockages on the base die 310, which supports flexible routing across the PUs 360, die-to-die (D2D) interconnections, control interconnections, and/or design for test (DFT) interconnections. Additionally, parasitics are reduced by utilizing the face-to-face (F2F) stacking between the base die 310 and the DRAM die 330. Using larger TSVs in the base die 310 supports connection of the package bumps 304 with improved mechanical integrity and power distribution network (PDN) functionality. A process of forming an extreme-bandwidth three-dimensional (3D) stacked memory having a base die configured for flexible processing unit (PU) placement is illustrated, for example, in FIGS. 6A to 6F.

FIGS. 6A to 6F illustrate a process of forming the extreme-bandwidth 3D stacked memory chip 300 of FIG. 3, having a base die configured for flexible processing unit (PU) placement, according to various aspects of the present disclosure. The process of forming the extreme-bandwidth 3D stacked memory chip 300 of FIG. 3 begins in FIG. 6A.

FIG. 6A illustrates a first step 600 in the process of forming the extreme-bandwidth 3D stacked memory chip 300 of FIG. 3, according to various aspects of the present disclosure. At the first step 600, a DRAM wafer-die 602 is stacked face-down on a base wafer-die 604 (a.k. a. a logic wafer-die) that is face-up according to a wafer-to-wafer (W2W) stacking. In this example, the base wafer-die 604 includes an active layer 314 having a front-end-of-line (FEOL) layer, including transistors (Xtors), and a back-end-of-line (BEOL) layer on the FEOL layer. Similarly, the DRAM wafer-die 602 includes an active layer 334 having an FEOL layer (e.g., Xtors), and a BEOL layer contacted to the BEOL layer of the base wafer-die 604, according to a face-to-face (F2F) stacking. It should be apparent to one of skill in the art that the base wafer-die 604 and/or the DRAM wafer-die 602 can include more than one FEOL layers and/or more than one BEOL layers. However, to simplify and to avoid obscuring the illustration, only one FEOL layer and one BEOL layer are shown in each of the base wafer-die 604 and the DRAM wafer die 602 in the current example.

In this example, a via-middle and redistribution layer (RDL) process forms the logic/signal TSV 312 through the base die 310 and into the BEOL layer of the active layer 314 of the base die 310. Similarly, a via-middle and RDL process forms the TSV groups 340 through the DRAM die 330 and into the BEOL layer of the active layer 334 of the DRAM die 330.

FIG. 6B illustrates a second step 610 in the process of forming the extreme-bandwidth 3D stacked memory chip 300 of FIG. 3, according to various aspects of the present disclosure. At the second step 610, the DRAM wafer-die 602 of FIG. 6A is thinned to form a first memory die 330-1, face-down (e.g., active layer 334) on the active layer 314 of the base wafer-die 604. In this example, thinning of the DRAM wafer-die 602 reveals the TSV groups 340 through a backside of the DRAM die 330.

FIG. 6C illustrates a third step 620 in the process of forming the extreme-bandwidth 3D stacked memory chip 300 of FIG. 3, according to various aspects of the present disclosure. At the third step 620, a DRAM wafer-die 622 is stacked through wafer-to-wafer (W2W) stacking on the DRAM die 330-1. In this example, the DRAM wafer-die 622 includes an active layer 334 having an FEOL layer, including transistors (Xtors), and a BEOL layer on the FEOL layer. Additionally, a via-middle and RDL process forms the TSV groups 340 through the DRAM wafer-die 622 and into the BEOL layer of the active layer 334 of the DRAM wafer-die 622.

FIG. 6D illustrates a fourth step 630 in the process of forming the extreme-bandwidth 3D stacked memory chip 300 of FIG. 3, according to various aspects of the present disclosure. At the fourth step 630, the DRAM wafer-die 622 of FIG. 6C is thinned to form a second memory die 330-2, face-down (e.g., active layer 334) on the first memory die 330-1. In this example, thinning of the DRAM wafer-die 622 reveals the TSV groups 340 through a backside of the second memory die 330-2.

FIG. 6E illustrates a fifth step 640 in the process of forming the extreme-bandwidth 3D stacked memory chip 300 of FIG. 3, according to various aspects of the present disclosure. At the fifth step 640, a DRAM wafer-die is stacked through W2W stacking on the second memory die 330-2 and thinned to form a third memory die 330-3, face-down (e.g., active layer 334) on the second memory die 330-2. In this example, the via-last/via-middle and RDL process forms the TSV groups 340 through the third memory die 330-3, the FEOL layer and into the BEOL layer of the active layer 334 of the third memory die 330-3.

FIG. 6F illustrates a last step 650 in the process of forming the extreme-bandwidth 3D stacked memory chip 300 of FIG. 3, according to various aspects of the present disclosure. At the last step 650, the base wafer-die 604 of FIG. 6E is thinned to form the base die 310. In this example, thinning of the base wafer-die 604 reveals the logic/signal TSV 312 through the base die 310 and into the BEOL layer of the active layer 314 of the base die 310 at a backside of the base die 310. In FIG. 6A-6F, the memory dies 330 are stacked back-to-face. However, this is merely an example. The orientations of the memory dies 300 are flexible.

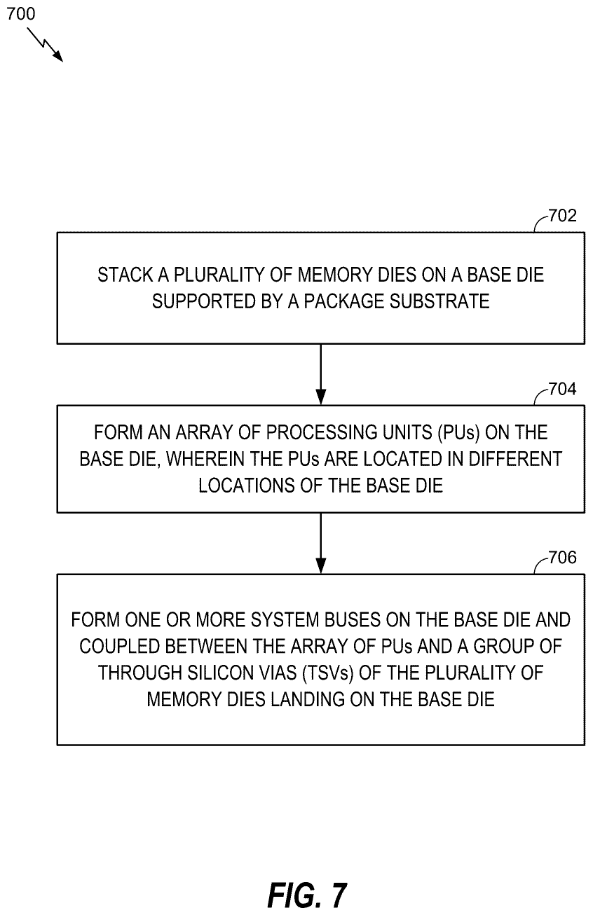

A process flow for forming an extreme-bandwidth 3D stacked memory chip is illustrated, for example, in FIG. 7, which is a process flow diagram illustrating a method 700 for forming an extreme-bandwidth three-dimensional (3D) stacked memory chip, having a base die configured for flexible processing unit (PU) placement, according to various aspects of the present disclosure. The method 700 begins at block 702, in which a plurality of memory dies are stacked on a base die supported by a package substrate. For example, as shown in FIG. 3, the base die 310 supports stacking of memory dies 330 (e.g., dynamic random-access memory (DRAM) dies) on the base die 310. In this example, the memory dies 330 are arranged using a back-to-face stacking of the DRAM dies on the face of the base die 310, according to a face-to-face (F2F) stacking. The number of memory dies stacked on the base die 310 varies in different implementations. But again, the orientations of the base die 310 and of the memory dies 330 are flexible.

At block 704, an array of processing units (PUs) are formed on the base die. For example, as shown in FIG. 4 illustrates placement of an array of PUs 360 (360-1, 362-2, . . . , 362-12) on the base die 310. The overhead view 400 of the extreme-bandwidth 3D stacked memory chip 300 of FIG. 3 further illustrates interconnects of the TSV groups 340 and lateral routing of the system bus 350 and DRAM banks 332. Again, the PUs 360 may be located at different locations of the base die 310.

At block 706, one or more system buses 350 are formed on the base die and coupled between the array of PUs and a group of through silicon vias (TSVs) of the plurality of memory dies landing on the base die. For example, as shown in FIG. 3, the BEOL layer of the DRAM die 330 and the BEOL layer of the base die 310 are utilized to form the one or more system buses 350. In this example, the one or more system buses 350 provide lateral connections between the TSV groups 340 and an array of processing units (PUs) 360 in the active layer 314 of the base die 310. Additionally, micro-bank connections 352, 354 to the TSV groups 340 are also shown. In some implementations, the TSV groups 340 are rerouted using the system bus 350 to provide access to the array of PUs 360 and/or a physical IO module (PHY) 320 of the base die 310.

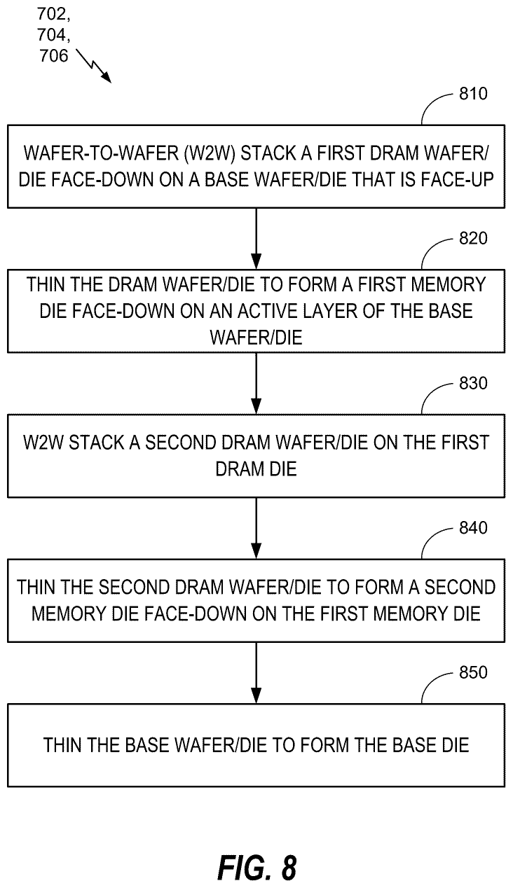

FIG. 8 illustrates a process flow for a particular implementation of the blocks of FIG. 7. At block 810, a first DRAM wafer-die 602 can be wafer-to-wafer (W2W) stacked on a base wafer-die 604 that is face-up. Block 810 may correspond to FIG. 6A.

At block 820, the first DRAM wafer-die 602 thinned to form a first memory die 330-1 face-down on an active layer 314 of the base wafer-die 604. Block 820 may correspond to FIG. 6B.

At block 830, a second DRAM wafer-die 622 may be W2W stacked on the first DRAM die 330-1. Block 830 may correspond to FIG. 6C.

At block 840, the second DRAM wafer-die 622 may be thinned to form a second memory die 330-2 face-down on the first memory die 330-1. Block 840 may correspond to FIG. 6D. Note that blocks 830 and 840 may be repeated to form further stacked memory dies such as the third memory die 330-3 (e.g., see FIG. 6E).

At block 850, the base wafer-die 604 may be thinned to form the base die 310. Block 850 may correspond to FIG. 6F.

The following should be noted regarding the flow indicated in FIG. 7-8. Unless otherwise indicated, the flow of blocks do not necessarily limit the ordering in which the blocks may be performed. In other words, the blocks may be performed in any order that is logical.

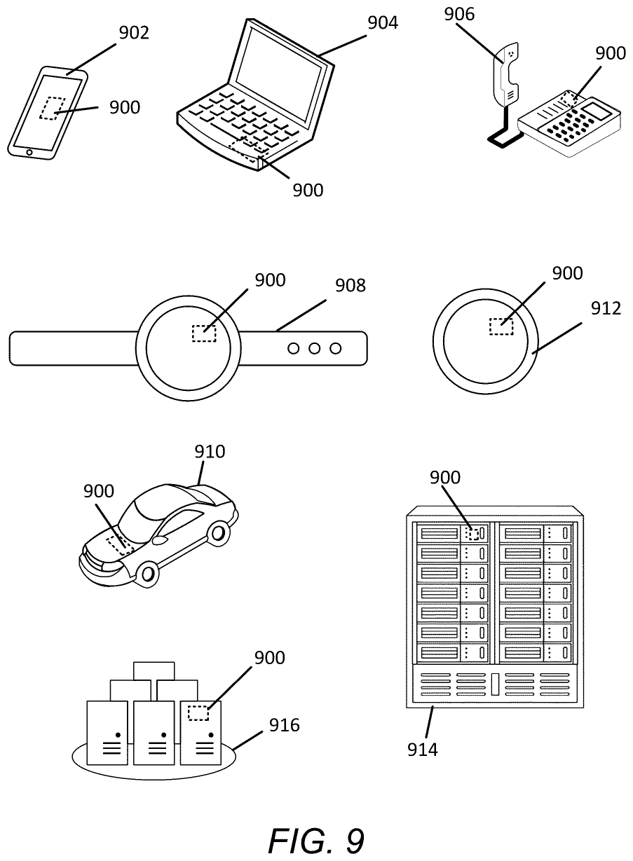

FIG. 9 is a block diagram showing an exemplary wireless communications system 900 in which a configuration of the disclosure may be advantageously employed. For purposes of illustration, FIG. 9 shows three remote units 920, 930, and 950, and two base stations 940. It will be recognized that wireless communications systems may have many more remote units and base stations. Remote units 920, 930, and 950 include integrated circuit (IC) devices 925A, 925C, and 925B that include the disclosed high-bandwidth 3D stacked memory chip. It will be recognized that other devices may also include the disclosed high-bandwidth 3D stacked memory chip, such as the base stations, switching devices, and network equipment. FIG. 9 shows forward link signals 980 from the base stations 940 to the remote units 920, 930, and 950, and reverse link signals 990 from the remote units 920, 930, and 950 to the base stations 940.

FIG. 9 illustrates various apparatuses (e.g., electronic devices) in which any of the semiconductor devices and/or electronic packages (e.g., 3D stacked memory packages) disclosed herein may be integrated, according to aspects of the disclosure. In an aspect, the semiconductor devices and/or electronic packages 900 may be integrated into user equipment (UE), including, by way of example and not limitation, a mobile phone device 902, a laptop computer device 904, a fixed-location terminal device 906, or a wearable device 908.

In other aspects, the semiconductor devices and/or electronic packages 900 may be integrated into electronic devices utilized in automotive applications. Such devices may include, by way of example and not limitation, sensors, controllers, processors, infotainment devices, and the like, which may be installed in a vehicle 910.

In yet other aspects, the semiconductor devices and/or electronic packages 900 may be integrated into a short-range device (SRD) 912. The SRD 912 may comprise, for example, one or more sensors, robotic machines, product code identifiers, electronic pricing and display labels, Internet of Things (IoT) devices, radio frequency identification (RFID) devices, Bluetooth Low Energy® (BLE) devices, or other similar devices.

In further aspects, the semiconductor devices and/or electronic packages 900 may be integrated into a server 914. The server 914 may comprise a computer system configured to provide services, data, or resources to other computers over a network. Such a server 914 may include one or more processors, integrated memory devices, power supplies, or other components mounted in one or more racks.

In yet other aspects, the semiconductor devices and/or electronic packages 900 may be integrated into a data center 916. The data center 916 may comprise a facility configured with one or more servers, storage devices, networking devices, and other supporting devices for storing, processing, and managing data.

The semiconductor devices and/or electronic packages 900 disclosed herein may be fabricated in various package configurations, including, but not limited to, side-by-side (SxS) packages, system-in-package (SiP) configurations, integrated circuit (IC) packages, package-on-package (PoP) devices, or any other suitable packaging configuration, whether disclosed herein or known in the art.

It will be appreciated, based on the teachings of the present disclosure, that the various apparatuses 902, 904, 906, 908, 910, 912, 914, and 916 illustrated in FIG. 9 are merely exemplary. Other apparatuses in which the semiconductor devices and/or electronic packages 900 may be integrated include, without limitation, mobile devices, hand-held personal communication system (PCS) units, portable data units (e.g., personal digital assistants), global positioning system (GPS)-enabled devices, navigation devices, set-top boxes, music players, video players, entertainment units, fixed-location data units, communication devices, smartphones, tablets, computers, wearable devices, servers, routers, memory devices, data centers, automotive electronic devices, Internet of Things (IoT) devices, or any combination thereof.

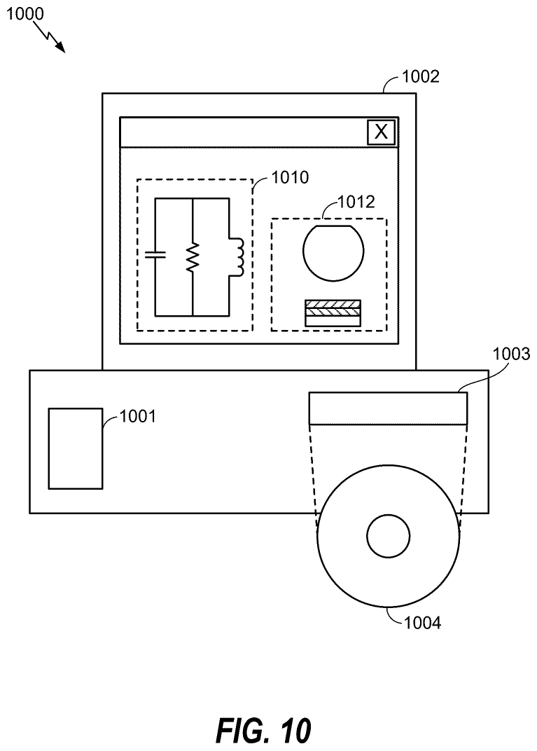

FIG. 10 is a block diagram illustrating a design workstation used for circuit, layout, and logic design of a semiconductor component, such as the high-bandwidth three-dimensional (3D) stacked memory chip disclosed above. A design workstation 1000 includes a hard disk 1001 containing operating system software, support files, and design software such as Cadence or OrCAD. The design workstation 1000 also includes a display 1002 to facilitate design of a circuit 1010 or an integrated circuit (IC) component 1012, such as a high-bandwidth 3D stacked memory chip. A storage medium 1004 is provided for tangibly storing the design of the circuit 1010 or the IC component 1012 (e.g., the high-bandwidth 3D stacked memory chip). The design of the circuit 1010 or the IC component 1012 may be stored on the storage medium 1004 in a file format such as GDSII or GERBER. The storage medium 1004 may be a CD-ROM, DVD, hard disk, flash memory, or other appropriate device. Furthermore, the design workstation 1000 includes a drive apparatus 1003 for accepting input from or writing output to the storage medium 1004.

Data recorded on the storage medium 1004 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1004 facilitates the design of the circuit 1010 or the IC component 1012 by decreasing the number of processes for designing semiconductor wafers.

The foregoing disclosed devices and functionalities may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and packaged into an antenna on glass device. The antenna on glass device may then be employed in devices described herein.

Implementation examples are described in the following numbered clauses:
1. A three-dimensional (3D) stacked memory package, comprising:
a base die;
a plurality of memory dies stacked on the base die;
a package substrate supporting the base die;
a plurality of processing units (PUs) arranged on the base die, wherein the plurality of PUs are located at different locations of the base die; and
one or more system buses on the base die and coupled between the one or more PUs and through silicon via (TSV) groups of the plurality of memory dies landing on the base die.
2. The 3D stacked memory package of clause 1, wherein the one or more system buses comprise back-end-of-line (BEOL) layers of the base die and BEOL layers of the plurality of memory dies.
3. The 3D stacked memory package of any of clauses 1-2, further comprising micro-bank connections between the TSV groups and micro-banks of the plurality of memory dies.
4. The 3D stacked memory package any of clauses 1-3, further comprising a system-on-chip (SoC) on the package substrate and having an SoC physical layer (PHY) coupled to a PHY of the base die.
5. The 3D stacked memory package any of clauses 1-4, wherein a face of the base die is oriented towards the plurality of memory dies and a back of the base die is oriented towards the package substrate.
6. The 3D stacked memory package of clause 5, wherein a memory die of the plurality of memory dies is stacked face-to-face (F2F) with the base die.
7. The 3D stacked memory package any of clauses 5-6, wherein a back-end-of-line (BEOL) layer of the base die is coupled to a BEOL layer of the memory die of the plurality of memory dies.
8. The 3D stacked memory package any of clauses 5-7,
wherein a first pair of vertically adjacent memory dies are stacked face-to-face, or
wherein a second pair of vertically adjacent memory die are stacked back-to-back, or
both.
9. The 3D stacked memory package any of clauses 5-8,
wherein a face of a first memory die is closer to the base die than a back of the first memory die, or
wherein a face of a second memory die is further from the base die than a back of the second memory die, or both.
10. The 3D stacked memory package any of clauses 1-9, wherein the one or more PUs comprise an array of PUs on the base die.
11. The 3D stacked memory package any of clauses 1-10, further comprising a plurality of signal TSVs extending through the base die.
12. The 3D stacked memory package of clause 11, wherein the base die comprises a physical layer (PHY) coupled to the plurality of signal TSVs.
13. The 3D stacked memory package any of clauses 1-12, further comprising package bumps (304) between the base die and the package substrate.
14. The 3D stacked memory package any of clauses 1-13, wherein the 3D stacked memory package is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, a data center, a memory device, and a device in an automotive vehicle.
15. A method of forming a three-dimensional (3D) stacked memory package, the method comprising:
stacking a plurality of memory dies on a base die supported by a package substrate;
forming an array of processing units (PUs) on the base die, wherein the PUs are located at different locations of the base die; and
forming one or more system buses on the base die and coupled between the array of PUs and through silicon via (TSV) groups of the plurality of memory dies landing on the base die.
16. The method of clause 15, wherein the one or more system buses comprise back-end-of-line (BEOL) layers of the base die and BEOL layers of the plurality of memory dies.
17. The method of any of clauses 15-16, further comprising forming micro-bank connections between the TSV groups and micro-banks of the plurality of memory dies.
18. The method of any of clauses 15-17, further comprising forming a system-on-chip (SoC) on the package substrate and having an SoC physical IO module (PHY) coupled to a PHY of the base die.
19. The method of any of clauses 15-18, wherein a face of the base die is oriented towards the plurality of memory dies and a back of the base die is oriented towards the package substrate.
20. The method of clause 19, wherein a memory die of the plurality of memory dies is stacked face-to-face (F2F) with the base die.
21. The method of any of clauses 19-20, wherein a back-end-of-line (BEOL) layer of the base die is coupled to a BEOL layer of the memory die of the plurality of memory dies.
22. The method of any of clauses 19-21,
wherein a first pair of vertically adjacent memory dies are stacked face-to-face, or
wherein a second pair of vertically adjacent memory die are stacked back-to-back, or
both.
23. The method of any of clauses 19-22,
wherein a face of a first memory die is closer to the base die than a back of the first memory die, or
wherein a face of a second memory die is further from the base die than a back of the second memory die, or
both.
24. The method of any of clauses 15-23, wherein the plurality of memory dies comprise dynamic random-access memory (DRAM) dies.
25. The method of any of clauses 15-24, further comprising forming a plurality of signal TSVs extending through the base die.
26. The method of clause 25, further comprises forming a physical IO module (PHY) coupled to the plurality of signal TSVs.
27. The method of any of clauses 15-26, further comprising forming package bumps (304) between the base die and the package substrate.
28. The method of any of clauses 15-27, wherein forming the stacking the plurality of memory dies, forming the array of processing units (PUs) on the base die, and forming the one or more system buses on the base die comprise:
wafer-to-wafer (W2W) stacking a first DRAM wafer-die face-down on a base wafer-die that is face-up;
thinning the first DRAM wafer-die to form a first memory die face-down on an active layer of the base wafer-die;
W2W stacking a second DRAM wafer-die on the first DRAM die;
thinning the second DRAM wafer-die to form a second memory die face-down on the first memory die; and
thinning the base wafer-die to form the base die.

For a firmware and/or software implementation, the methodologies may be implemented with modules (e.g., procedures, functions, etc.) that perform the functions described. A machine-readable medium tangibly embodying instructions may be used in implementing the methodologies described. For example, software codes may be stored in a memory and executed by a processor unit. Memory may be implemented within the processor unit or external to the processor unit. As used, the term “memory” refers to types of long term, short term, volatile, nonvolatile, or other memory and is not limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer. Disk and disc, as used, include compact disc (CD), laser disc, optical disc, digital versatile disc (DVD), floppy disk and Blu-ray® disc, where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communications apparatus. For example, a communications apparatus may include a transceiver having signals indicative of instructions and data. The instructions and data are configured to cause one or more processors to implement the functions outlined in the claims.

Although the present disclosure and its advantages have been described in detail, various changes, substitutions, and alterations can be made without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above, and below may refer to sides of a substrate or electronic device. Moreover, the scope of the present application is not intended to be limited to the configurations of the process, machine, manufacture, composition of matter, means, methods, and steps described in the specification. As one of ordinary skill in the art will readily appreciate from the disclosure, processes, machines, manufacture, compositions of matter, means, methods, or steps, presently existing or later to be developed that perform the same function or achieve the same result as the corresponding configurations described may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the application and design constraints imposed on the overall system. Skilled artisans may implement the described functionality in varying ways for each application, but such implementation decisions should not be interpreted as causing a departure from the scope of the present disclosure.

The various illustrative logical blocks, modules, and circuits described in connection with the disclosure may be implemented or performed with a general-purpose processor, a digital signal processor (DSP), an application specific integrated circuit (ASIC), a field programmable gate array (FPGA), or other programmable logic device, discrete gate or transistor logic, discrete hardware components, or any combination thereof designed to perform the functions described. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

The previous description of the disclosure is provided to enable any person skilled in the art to make or use the disclosure. Various modifications to the disclosure will be readily apparent to those skilled in the art, and the generic principles defined may be applied to other variations without departing from the spirit or scope of the disclosure. Thus, the disclosure is not intended to be limited to the examples and designs described but is to be accorded the widest scope consistent with the principles and novel features disclosed.

What is claimed is:

1. A three-dimensional (3D) stacked memory package, comprising:
a base die;
a plurality of memory dies stacked on the base die;
a package substrate supporting the base die;
a plurality of processing units (PUs) arranged on the base die, wherein the plurality of PUs are located at different locations of the base die; and
one or more system buses on the base die and coupled between the one or more PUs and through silicon via (TSV) groups of the plurality of memory dies landing on the base die.

2. The 3D stacked memory package of claim 1, wherein the one or more system buses comprise back-end-of-line (BEOL) layers of the base die and BEOL layers of the plurality of memory dies.

3. The 3D stacked memory package of claim 1, further comprising micro-bank connections between the TSV groups and micro-banks of the plurality of memory dies.

4. The 3D stacked memory package of claim 1, further comprising a system-on-chip (SoC) on the package substrate and having an SoC physical layer (PHY) coupled to a PHY of the base die.

5. The 3D stacked memory package of claim 1, wherein a face of the base die is oriented towards the plurality of memory dies and a back of the base die is oriented towards the package substrate.

6. The 3D stacked memory package of claim 5, wherein a memory die of the plurality of memory dies is stacked face-to-face (F2F) with the base die.

7. The 3D stacked memory package of claim 5, wherein a back-end-of-line (BEOL) layer of the base die is coupled to a BEOL layer of the memory die of the plurality of memory dies.

8. The 3D stacked memory package of claim 5,
wherein a first pair of vertically adjacent memory dies are stacked face-to-face, or
wherein a second pair of vertically adjacent memory die are stacked back-to-back, or
both.

9. The 3D stacked memory package of claim 5,
wherein a face of a first memory die is closer to the base die than a back of the first memory die, or
wherein a face of a second memory die is further from the base die than a back of the second memory die, or
both.

10. The 3D stacked memory package of claim 1, further comprising a plurality of signal TSVs extending through the base die.

11. The 3D stacked memory package of claim 10, wherein the base die comprises a physical layer (PHY) coupled to the plurality of signal TSVs.

12. The 3D stacked memory package of claim 1, wherein the 3D stacked memory package is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, a data center, a memory device, and a device in an automotive vehicle.

13. A method of forming a three-dimensional (3D) stacked memory package, the method comprising:
stacking a plurality of memory dies on a base die supported by a package substrate;
forming an array of processing units (PUs) on the base die, wherein the PUs are located at different locations of the base die; and
forming one or more system buses on the base die and coupled between the array of PUs and through silicon via (TSV) groups of the plurality of memory dies landing on the base die.

14. The method of claim 13, wherein the one or more system buses comprise back-end-of-line (BEOL) layers of the base die and BEOL layers of the plurality of memory dies.

15. The method of claim 13, further comprising forming micro-bank connections between the TSV groups and micro-banks of the plurality of memory dies.

16. The method of claim 13, wherein a face of the base die is oriented towards the plurality of memory dies and a back of the base die is oriented towards the package substrate.

17. The method of claim 16, wherein a memory die of the plurality of memory dies is stacked face-to-face (F2F) with the base die.

18. The method of claim 13, further comprising forming a plurality of signal TSVs extending through the base die.

19. The method of claim 18, further comprises forming a physical IO module (PHY) coupled to the plurality of signal TSVs.

20. The method of claim 13, wherein forming the stacking the plurality of memory dies, forming the array of processing units (PUs) on the base die, and forming the one or more system buses on the base die comprise:
wafer-to-wafer (W2W) stacking a first DRAM wafer-die face-down on a base wafer-die that is face-up;
thinning the first DRAM wafer-die to form a first memory die face-down on an active layer of the base wafer-die;
W2W stacking a second DRAM wafer-die on the first DRAM die;
thinning the second DRAM wafer-die to form a second memory die face-down on the first memory die; and
thinning the base wafer-die to form the base die.
